(19) United States
(12) Patent Application Publication
(10) Pub. No.: US 2009/0246716 A1
(43) Pub. Date: Oct. 1, 2009

(54) HIGH REFRACTIVE INDEX SOL-GEL COMPOSITION AND METHOD OF MAKING PHOTO-PATTERNED STRUCTURES ON A SUBSTRATE

(75) Inventors: Mohanalingam Kathaperumal, Oceanside, CA (US); Shuangxi Wang, Corona, CA (US); Joshua Tillema, Oceanside, CA (US); Weiping Lin, Carlsbad, CA (US); Michiharu Yamamoto, Carlsbad, CA (US)

Correspondence Address: KNOBBE MARTENS OLSON & BEAR LLP, 2040 MAIN STREET, FOURTEENTH FLOOR, IRVINE, CA, 92614, US

(73) Assignee: NITTO DENKO CORPORATION, Osaka (JP)

(21) Appl. No.: 12/057,828

(22) Filed: Mar. 28, 2008

(51) Int. Cl. G03F 7/26; C07F 7/18; C09D 183/00; C07F 7/08

(52) U.S. Cl. 430/325; 556/482; 106/287.14; 556/440

(57) ABSTRACT

Described herein are sol-gel compositions, sol-gel composition precursors, and methods of fabricating photo-patterned structures on a substrate. The sol-gel compositions possess a combination of high refractive index and low optical loss, even without incorporating metal oxides or metal alkoxides. The sol-gel compositions are further useful in waveguide fabrication applications, especially at the telecommunication wavelength range of 1300-1600 nm. Furthermore, the fabrication of patterned structures using the sol-gel compositions described herein can be achieved in a variety of substrates, including, for example, silicon-on-silica substrates and molybdenum-on-glass substrates.

### BACKGROUND OF THE INVENTION

1. Field of the Invention

The invention relates to high refractive index, photo-pattemable organic and organometallic sol-gels and methods of making predetermined photo-patterned structures on a substrate.

2. Description of the Related Art

Advances in the art of photonic and optoelectronic devices for various applications, including telecommunication, along with active and passive waveguides, are in high demand in order to implement routing, switching, or filtering of optical information. The current technology to fabricate such waveguides requires complex processes such as epitaxial growth, reactive ion etching, ion implantation, etc. Some of the methods are more specific to the substrates used, for example, ion exchange works well with glass but it is not compatible with silicon processing. Other methods, such as sputtering, epitaxial growth, and evaporation work well with silicon substrates, but require multiple processing steps. Reactive ion etching is also a widely used technique, but it often leads to increased scattering loss which primarily causes formation of rough walls in the waveguides.

In most applications that utilize waveguides, it is desired to have low optical loss (including the propagation losses) around 1 dB/cm. It is also desirable to have the lower optical loss within the telecommunication wavelength window of 1300-1600 nm, which is the most suitable range for the telecom industry. Thus, the selection of materials that are useful for such telecommunication applications are very limited, as they generally have very low absorption/propagation losses.

One material that is useful in telecommunication applications is sol-gel compositions. Manufacturing methods using sol-gel compositions allow for the fabrication of glass ftom precursors using low temperature processing steps. Additionally, sol-gel methods provide for a wide range of compositions that are not easily accessible by conventional methods. Sol-gels materials are produced at room temperature using a hydrolysis-condensation polymerization reaction of suitable monomers. The sol-gel compositions can be obtained from metal alkoxide precursors, such as M(OR)₄, wherein O is oxygen, R is an alkyl chain, and M is a metal. Useful metals in the precursor include silicon, titanium, zirconium, and aluminum. Usually, the metal alkoxides are combined with organic polymerizable alkoxysilanes to produce an organically modified sol-gel. The organically modified sol-gels have the general formula of R′-M(OR)₃, wherein R′ is an organic moiety, and these materials are very stable to hydrolysis about the M-C bonds.

These organically modified sol-gel materials form good optical quality waveguide films. However, due to high optical loss of simple organically modified sol-gels arising from the large number of C—H and 0—H bonds from the organic moiety, it is ofien desirable to replace a large number of these C—H bonds with bonds that have low optical loss. One example of replacing the C—H bonds with low optical loss bonds is by using a low loss C—F bonds instead, which have lower IR absorption bands around 1000 cm⁻¹ compared to the C—H and O—H bonds, which fall in the range of 1500-1600 cm⁻. However, the introduction of a large number of C—F bonds has the disadvantage of leading to a decreased refractive index in the sol-gel composition. This becomes a problem particularly when high index sol-gels are required, as in telecommunication applications. As a result the highly desired sol-gel properties of having a high refractive index coupled with low optical loss at the telecommunication wavelength range between 1300-1600 nm is very difficult to obtain.

U.S. Pat. No. 5,100,764 to Paulson et al., the contents of which are hereby incorporated by reference, describes methods to make patterned metal oxide films using sol-gel processing steps. However, this reference contains no disclosure as to the manufacture of low optical loss, high refractive index waveguides for the telecommunication wavelength range of 1300-1600 nm. U.S. Pat. No. 6,908,723 to Fardad et al., the contents of which are hereby incorporated by reference, discloses photo-patternable sol-gels having a refractive index of 1.50 at 1550 nm by introducing C—F bonds along with a metal refractive index adjuster, preferably titanium, to a sol-gel. However, the maximum refractive index disclosed by Fardad et al. was only about 1.50. Furthermore, both references describe methods that use metal oxides other than silicon oxide to obtain patterned sol-gel materials, such as Ti—O bonds and Zr—O bonds.

### SUMMARY OF THE INVENTION

In view of the foregoing, the present invention provides a sol-gel material and methods of fabrication to produce low optical loss, high refractive index sol-gels. Embodiments of the sol-gels described herein can obtain refractive indices greater than 1.45 at the telecommunication wavelengths between 1300 and 1600 nm. In an embodiment, the refractive index is greater than about 1.50 at wavelengths between 1300 and 1600 nm. Even refractive index values greater than about 1.55, greater than about 1.60, greater than about 1.65, greater than about 1.70, or greater than about 1.75 at wavelengths between 1300 and 1600 nm are attainable with embodiments of the sol-gel compositions described herein. Furthermore, low propagation losses, for example, below about 1.5 dB/cm, below about 1.0 dB/cm, or below about 0.5 dB/cm at the telecommunication wavelengths between 1300 and 1600 nm are also obtained in some embodiments. The highly desirable combination of high refractive index coupled with low propagation loss is achievable using the sol-gel compositions described herein.

One useful application of the sol-gel materials described herein is waveguide fabrication. Sol-gels materials generally offer great advantages in waveguide fabrication using standard photolithographic techniques. For example, waveguides can be fabricated directly on the sol-gel material. This direct patterning of the waveguide greatly reduces the number of manufacturing steps. Furthermore, dry etch processing steps that are often required when using other materials and which have been shown to increase scattering losses, can be avoided. Waveguide fabrication using sol-gel compositions can involve only wet processing steps, thus reducing scattering losses. Embodiments of fabricated devices using the sol-gel compositions described herein have smooth walls.

Another advantage to the sol-gel compositions described herein is that polymerizable moieties can be directly attached to the organic portion of the sol-gel material. This allows UV exposure patterning through cross-linking of organic materials by using a variety of organic moieties.

Because of the possibility of achieving tunable refractive index and photo-patternability, sol-gels have been used both as buffer materials and cladding materials. When used as a cladding or buffer layer, the refractive index of the sol-gel material is higher than that of the substrate or the polymer layer, if any, already coated on the substrate. As a result it becomes important to strike a balance between the refractive index and the optical loss of the sol-gel systems.

Described herein is a sol-gel composition comprising a recurring unit of the formula (I):

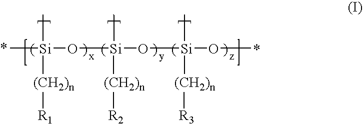

wherein R₁ is a photo cross-linkable group, R₂ is an aromatic group optionally substituted with at least one halogen or deuterium atom, and R₃ is an aromatic group selected from the group consisting of phenyl, biphenyl, naphthyl, anthracenyl, phenanthrenyl, pyrenyl, quinolinyl, tetracenyl, perylenyl, and pentacenyl. In an embodiment, each n in formula (I) is independently selected to be an integer in the range of 0 to about 10. Each of x, y, and z can also be independently selected, and can be in the range of 0 to about 20. Further embodiments of formula (I) are described below.

The sol-gel compositions described herein can be prepared according to a method that comprises the steps of (a) mixing two organically modified silane precursors with an aqueous acidic solution to form a mixture, wherein one of the silane precursors is a monomer according to the formula (V) and the other silane precursor is a monomer according to the formula (VI):

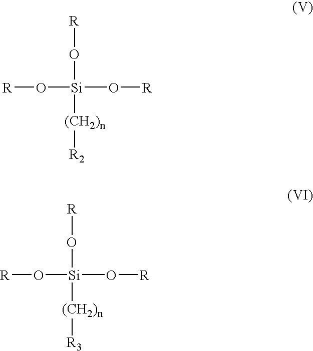

wherein R₂ in formula (V) is an aromatic group optionally substituted with at least one halogen or deuterium atom, R₃ in formula (VI) is an aromatic group selected from the group consisting of phenyl, biphenyl, naphthyl, anthracenyl, phenanthrenyl, pyrenyl, quinolinyl, tetracenyl, perylenyl and pentacenyl, each R in formulae (V) and (VI) is independently selected to be a lower alkyl group, and each n in formulae (V) and (VI) is independently an integer in the range of 0 to about 10; (b) agitating the mixture until the —OR groups in formulae (V) and (VI) are at least partially hydrolyzed; (c) adding a third organically modified silane precursor to the resulting mixture, wherein the third silane precursor is a monomer according to the formula (VII):

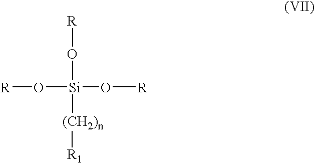

wherein R₁ in formula (VII) is a photo cross-linkable group, each R in formula (VII) is independently selected to be a lower alkyl group, and n in formula (VII) is selected to be an integer in the range of 0 to about 10; (d) agitating the solution until the solution is mixed; (e) adding additional solvent while agitating to further complete hydrolysis; and (f) aging the solution until condensation occurs and yields a viscous liquid. In an embodiment, solvent is removed during agitation, which facilitates condensation and aging.

Also described herein are various sol-gel precursors. For example, the sol-gel precursor can comprise a monomer of the formulae (V), (VI), or (VII). In an embodiment, a sol-gel precursor comprises a compound selected from anthracenyl trimethoxysilane, phenanthrenyl triethoxysilane, naphthyl trimethoxysilane, pyrenyl trimethoxysilane, bis(pyrenyl) dimethoxysilane, bis(pyrenyl) diethoxysilane, perylenyl triethoxysilane, or perylenyl 3,9-bis(triethoxysilane). Each compound can be present in any of its isomeric forms. For example, any anthracenyl trimethoxysilane can be used, including 1-anthracenyl trimethoxysilane, 2-anthracenyl trimethoxysilane, 9-anthracenyl trimethoxysilane, and combinations thereof. An anthracenyl trimethoxysilane can alternatively be referred to as a trimethoxysilyl anthracene.

Further described herein is a method of making photo-pattemed structures on a substrate. The manufacturing steps of making a photo-patterned structure on a substrate can comprise the steps of (a) coating a sol-gel on at least a portion of the substrate to form a film, wherein the sol-gel comprises a recurring unit of the formula (I) or formula (Ia) described below as described herein; (b) soft baking the film to form a sol-gel film; (c) positioning a mask over the sol-gel film, wherein the mask comprises at least one opening that defines a pattern design; (d) exposing at least a portion of the sol-gel film to ultra-violet radiation through the at least one opening in the mask to create an unexposed portion of the film and an exposed portion of the film, wherein the exposed portion of the film is insoluble to a selected solvent through the full thickness of the film; (e) removing the unexposed portion of the film by washing it with the selected solvent; and (f) hard baking the film at a reduced pressure.

The sol-gel materials described herein are compatible with other metal oxides, which can be present in a large or small amount. In an embodiment, the sol-gel composition comprises less than 1 mol % of metal atoms other than Si. In an embodiment, the sol-gel composition is substantially free of metal atoms other than Si. In an embodiment, the sol-gel composition contains no metal atoms other than Si. In an embodiment, no other metal precursors besides those containing Si are used for adjusting the refractive index of the sol-gel compositions.

These and other embodiments are described in greater detail below.

### BRIEF DESCRIPTION OF THE DRAWINGS

FIG. 1 shows an embodiment of a substrate comprising sol-gel composition and how the electrical conductivity can be measured.

FIG. 2 is a graph measuring the electrical current as a function of bias voltage at room temperature of several sol-gel compositions.

FIG. 3 is a graph measuring the electrical current as a function of temperature of several sol-gel compositions.

### DETAILED DESCRIPTION OF THE PREFERRED EMBODIMENTS

Described herein are sol-gel compositions, sol-gel composition precursors, and methods of fabricating photo-patterned structures on a substrate. The sol-gel compositions and fabrication methods described herein can produce high refractive index, low optical loss sol-gels, even without incorporating metal oxides or metal alkoxides. In some embodiments, the sol-gel compositions described herein have high refractive index and low optical loss at the telecommunication wavelength range of 1300-1600 nm. Furthermore, the fabrication of patterned structures using the sol-gel compositions described herein can be achieved in a variety of substrates, including, for example, silicon-on-silica substrates and molybdenum-on-glass substrates.

In an embodiment, the sol-gel composition comprises a recurring unit of the formula (I), as described above. In an embodiment, each n in formula (I) is independently an integer in the range of 0 to about 5. In an embodiment, each n in formula (I) is independently an integer in the range of 0 to about 3.

Each of x, y, and z in formula (I) can be independently selected, as discussed above. The number of siloxane units present in a recurring unit of formula (I) can be determined by the numbers for x, y, and z. For example, when x=1, y=1, and z=1, then formula (I) contains three different siloxane units. Preferably, the recurring unit of formula (I) comprises at least two different siloxane units. In an embodiment, the recurring unit of formula (I) comprises three different siloxane units. In an embodiment, x in formula (I) is in the range of 1 to 3, y in formula (I) is in the range of 0 to 3, and z in formula (I) is in the range of 0 to 3. In an embodiment, at least one of y or z is at least 1. In an embodiment, x in formula (I) is 1, y in formula (I) is 0 or 1, and z in formula (I) is 0 or 1, provided that at least one of y and z is 1. In an embodiment, x in formula (I) is 1, y in formula (I) is 0 or 1, and z in formula (I) is 1.

The siloxane unit of formula (I) that comprises R₁ is a photo cross-linkable siloxane unit. The photo cross-linkable group R₁ can comprise various groups that cross-link upon irradiation with light. Preferably, the photo cross-linkable group comprises a double bond. In an embodiment, the photo-crosslinkable group comprises a methacrylate group, a vinyl group, an epoxy group, a methacryloxy group, or an acryloxy group. In an embodiment, upon irradiation with light, for example, UV light, the photo cross-linkable group reacts to form covalent bonds that link various molecular chains within the sol-gel to one another. UV radiation can be performed, for example, after appropriate masking and patterning steps.

The degree of cross-linking can vary and be adjusted by those having ordinary skill in the art. Factors used to control the degree of cross-linking include the number of cross-linkable units dispersed throughout the sol-gel composition, the distance between cross-linkable units, the amount of time the sol-gel composition is exposed to irradiation, and the intensity of the irradiation. In an embodiment, the photo cross-linkable group is selected from the group consisting of methacrylate and vinyl.

The siloxane unit of formula (1) that comprises R₂ is a siloxane unit that comprises an aromatic group optionally substituted with at least one halogen or deuterium atom. Various types of aromatic groups may be used. For example, the aromatic group can be phenyl, biphenyl, naphthyl, anthracenyl, phenanthrenyl, pyrenyl, quinolinyl, tetracenyl, perylenyl, or pentacenyl. The aromatic group optionally substituted with one or more halogen or deuterium atoms, when substituted, can comprise fluorine, chlorine, bromine, iodine, deuterium, or a combination thereof

In an embodiment, the aromatic group of R₂ is substituted with fluorine or chlorine. In an embodiment, R₂ is a fluorinated aromatic group, a perfluorinated aromatic group, a brominated aromatic group, or a perbrominated aromatic group. In an embodiment, R₂ is a perfluorinated aromatic group or a brominated aromatic group. For example, R₂ can be a pentafluorophenyl group, a bispentafluorophenyl group, or a bromophenyl group. The degree of halogen or deuterium substitution on the aromatic group can vary. Any number between one hydrogen atom and all of the hydrogen atoms on an aromatic group can be substituted with a halogen atom or deuterium. For example, where the aromatic group comprises a phenyl group, the phenyl group can be substituted with one, two, three, four, or five halogen and/or deuterium atoms. In an embodiment, the aromatic group is substituted with bromine. In an embodiment, the halogenated aromatic group comprises bromoanthracenyl.

The siloxane unit of formula (I) that comprises R₃ is a siloxane unit that comprises an aromatic group. The siloxane unit comprising R₃ is primarily responsible for providing the high refractive index to the sol-gel compositions. Any aromatic group may be used for R₃. Non-limiting examples of suitable aromatic groups include phenyl, biphenyl, naphthyl, anthracenyl, phenanthrenyl, pyrenyl, quinolinyl, tetracenyl, perylenyl and pentacenyl. In an embodiment, the aromatic group is anthracenyl. The aromatic group can be connected to the siloxane unit, for example, by any suitable carbon atom of the aromatic group. For example, the aromatic group can be connected to the siloxane unit, either directly or through an alkyl linker, via replacement of any hydrogen atom.

The sol-gel compositions described herein, while not limited by theory of operation, are believed to attain high refractive index by the presence of the aromatic groups in the chemical structure of formula (I). Furthermore, the refractive index of the sol-gel compositions described herein can be adjusted by the addition of one or more halogen or deuterium atoms to the aromatic groups of R₂. For example, the aromatic groups of R₂ can be substituted with fluorine atom(s) or bromine atom(s). The sol-gel compositions described herein possess low optical loss due, in part, to the reduction of the number of aliphatic C—H linkages in the composition compared to other sol-gel compositions.

The aromatic moieties of R₂ and R₃ provide several advantageous properties, including (1) imparting a high refractive index to the sol-gel composition, (2) providing low optical loss due, in part, to the replacement of aliphatic C—H bonds with aromatic C—H linkages, (3) providing low IR absorption bands around 1000 cm⁻¹ by using carbon-halogen bonds, e.g. C—F bonds, and (4) a photo-patternable group can be also attached to the aromatic moiety.

Each siloxane unit represented in the formula (I) can be present in the sol-gel composition in various amounts. In an embodiment, the sol-gel composition comprises a selected mole percentage of recurring units of the formula (II):

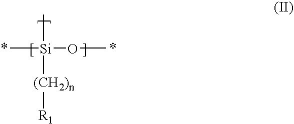

wherein R₁ is a photo cross-linkable group as described above, n is an integer in the range of 0 to about 10, preferably an integer in the range of 0 to about 3, and the mole percentage of recurring units of the formula (II) is in the range of about 10 mol % to about 90 mol %. The recurring unit of formula (II) corresponds to the siloxane unit that comprises a photo cross-linkable group in formula (I). In an embodiment, the mole percentage of recurring units of the formula (II) is in the range of about 20 mol % to about 80 mol %. In an embodiment, the mole percentage of recurring units of the formula (II) is in the range of about 30 mol % to about 70 mol %. In an embodiment, the mole percentage of recurring units of the formula (II) is in the range of about 40 mol % to about 60 mol %.

In an embodiment, the sol-gel composition comprises a selected mole percentage of recurring units of the formula (III):

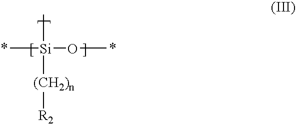

wherein R₂ is an aromatic group optionally substituted with halogen or deuterium atoms, n is an integer in the range of 0 to about 10, preferably an integer in the range of 0 to about 3, and the mole percentage of recurring units of the formula (III) is in the range of about 0 mol % to about 60 mol %. The recurring unit of formula (III) corresponds to the siloxane unit that comprises an aromatic group optionally substituted with halogen atoms in formula (1). In an embodiment, the mole percentage of recurring units of the formula (III) is in the range of about 0.1 mol % to about 50 mol %. In an embodiment, the mole percentage of recurring units of the formula (III) is in the range of about 5 mol % to about 40 mol %. In an embodiment, the mole percentage of recurring units of the formula (III) is in the range of about 10 mol % to about 30 mol %. In an embodiment, the mole percentage of recurring units of the formula (III) is in the range of about 15 mol % to about 25 mol %. In an embodiment, R₂ is a bromoanthracenyl.

In an embodiment, the sol-gel composition comprises a selected mole percentage of recurring units of the formula (IV):

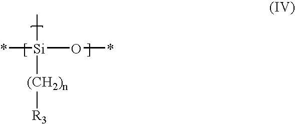

wherein R₃ is an aromatic group selected from the group consisting of phenyl, biphenyl, naphthyl, anthracenyl, phenanthrenyl, pyrenyl, quinolinyl, tetracenyl, perylenyl and pentacenyl, n is an integer in the range of 0 to about 10, preferably an integer of 0 to about 3, and the mole percentage of recurring units of the formula (IV) is in the range of about 0 mol % to about 90 mol %. The recurring unit of formula (IV) corresponds to the siloxane unit that comprises an aromatic group of R₃ in formula (I). In an embodiment, the mole percentage of recurring units of the formula (IV) is in the range of about 10 mol % to about 90 mol %. In an embodiment, the mole percentage of recurring units of the formula (IV) is in the range of about 15 mol % to about 75 mol %. In an embodiment, the mole percentage of recurring units of the formula (IV) is in the range of about 20 mol % to about 60 mol %. In an embodiment, the mole percentage of recurring units of the formula (IV) is in the range of about 30 mol % to about 50 mol %.

The total recurring units of the formulae (II), (III), and (IV) may comprise up to 100 mol % of the sol-gel composition. However, additional ingredients and/or impurities may be present such that the total recurring units of the formulae (II), (III), and (IV) does not comprise 100 mol % of the sol-gel composition. For example, the sol-gel composition can further comprise a photo-initiator, which can be present no matter which photo cross-linkable group is used. In an embodiment, the sol-gel composition further comprises a photo-initiator when the photo cross-linkable group is selected from the group consisting of epoxy, vinyl, methacryloxy, and acryloxy.

Any suitable photo-initiator can be used. Suitable photo-initiators cure the composition upon activation by UV light. Non-limiting examples of the photo-initiator include IRGACURE-184® (1-Hydroxy-cyclohexyl-phenyl-ketone) or IRGACURE-369® (2-Benzyl-2-dimethylamino-1-(4-morpholinophenyl)-butanone-1) (both of which are available from Ciba Specialty Chemicals). The amount of the photo-initiator can vary. In an embodiment, the photo-initiator is present in an amount in the range of about 0.1 weight % to about 10 weight % of the sol-gel composition. In an embodiment, the photo-initiator is present in an amount in the range of about 0.2 weight % to about 8 weight % of the sol-gel composition. In an embodiment, the photo-initiator is present in an amount in the range of about 0.5 weight % to about 5 weight % of the sol-gel composition.

The siloxane unit comprising aromatic group R₃ in formula (I) can further comprise a second aromatic group or an alkoxy group. For example, in an embodiment, there is provided a sol-gel composition comprising a recurring unit of the formula (Ia):

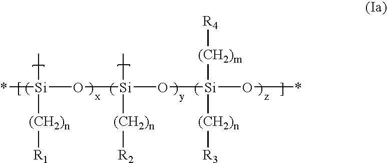

swherein R₁, R₂, and R₃ are defined independently in the same manner as defined above in Formula (I) and R₄ is —OR or an aromatic group selected from the group consisting of phenyl, biphenyl, naphthyl, anthracenyl, phenanthrenyl, pyrenyl, quinolinyl, tetracenyl, perylenyl, and pentacenyl. The aromatic group of R₄ is independently selected from the aromatic group selected for R₃ and R₄ can be the same or different as R₃. The R in formula (Ia) group comprises a lower alkyl group. In an embodiment, m is is independently an integer in the range of 0 to about 10. In an embodiment, each n, x, y, and z in formula (Ia) is defined independently in the same manner as defined above in formula (I).

Each of the variations and embodiments described herein that are applicable to the sol-gel composition comprising a recurring unit of formula (I) are also applicable to the sol-gel composition comprising a recurring unit of formula (Ia). In an embodiment, m in formula (Ia) is an integer in the range of 0 to about 3. In an embodiment, when m=0, R₄ is —OR.

The sol-gel composition that comprises a recurring unit of the formula (Ia) can comprise a selected mole percentage of recurring units of the formula (II) and formula (III) as defined above. In an embodiment, the sol-gel composition comprising a recurring unit of formula (Ia) comprises a selected mole percentage of recurring units of the formula (IVa):

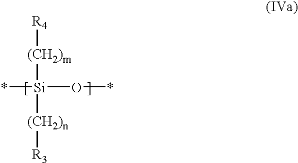

wherein R₃ is an aromatic group selected from the group consisting of phenyl, biphenyl, naphthyl, anthracenyl, phenanthrenyl, pyrenyl, quinolinyl, tetracenyl, perylenyl and pentacenyl, R₄ is —OR or an aromatic group selected from the group consisting of phenyl, biphenyl, naphthyl, anthracenyl, phenanthrenyl, pyrenyl, quinolinyl, tetracenyl, perylenyl, and pentacenyl, each m and n is independently selected to be an integer in the range of 0 to about 10, preferably an integer of 0 to about 3, and the mole percentage of recurring units of the formula (IVa) is in the range of about 0 mol % to about 90 mol %. The recurring unit of formula (IVa) corresponds to the siloxane unit that comprises groups of R₃ and R₄ in formula (Ia). In an embodiment, the mole percentage of recurring units of the formula (IVa) is in the range of about 10 mol % to about 90 mol %. In an embodiment, the mole percentage of recurring units of the formula (IVa) is in the range of about 15 mol % to about 75 mol %. In an embodiment, the mole percentage of recurring units of the formula (IVa) is in the range of about 20 mol % to about 60 mol %. In an embodiment, the mole percentage of recurring units of the formula (IVa) is in the range of about 30 mol % to about 50 mol %.

High refractive index values are obtained in embodiments of the sol-gel compositions described herein. In an embodiment, the refractive index is greater than about 1.45 at a telecommunication wavelength in the range of about 1300 to about 1600 nm. In an embodiment, the refractive index is greater than about 1.49 at a telecommunication wavelength in the range of about 1300 to about 1600 nm. In an embodiment, the refractive index is greater than about 1.50 at a telecommunication wavelength in the range of about 1300 to about 1600 nm. In an embodiment, the refractive index is greater than about 1.51, greater than about 1.52, greater than about 1.53, greater than about 1.54, greater than about 1.55, greater than about 1.56, greater than about 1.57, greater than about 1.58, greater than about 1.59, greater than about 1.60, greater than about 1.61, greater than about 1.62, greater than about 1.63, greater than about 1.64, greater than about 1.65, greater than about 1.66, greater than about 1.67, greater than about 1.68, greater than about 1.69, greater than about 1.70, greater than about 1.71, greater than about 1.72, greater than about 1.73, greater than about 1.74, and/or greater than about 1.75 at a telecommunication wavelength in the range of about 1300 to about 1600 nm. The refractive index for embodiments of the sol-gel compositions described herein is generally less than about 2.4.

Embodiments of the sol-gel compositions further possess the advantageous property of low optical loss to provide highly advantageous sol-gels. In an embodiment, the sol-gel composition has an optical loss less than about 1.5 dB/cm measured at a telecommunication wavelength in the range of about 1300 to about 1600 nm. In an embodiment, the sol-gel composition has an optical loss less than about 1.0 dB/cm measured at a telecommunication wavelength in the range of about 1300 to about 1600 nm. In an embodiment, the sol-gel composition has an optical loss less than about 0.75 dB/cm measured at a telecommunication wavelength in the range of about 1300 to about 1600 nm. In an embodiment, the sol-gel composition has an optical loss less than about 0.6 dB/cm measured at a telecommunication wavelength in the range of about 1300 to about 1600 nm. In an embodiment, the sol-gel composition has an optical loss less than about 0.5 dB/cm measured at a telecommunication wavelength in the range of about 1300 to about 1600 nm. In an embodiment, the sol-gel composition has an optical loss of about 0.4 dB/cm measured at a telecommunication wavelength in the range of about 1300 to about 1600 nm.

Variations of the recurring unit of formula (I) or formula (Ia) are further contemplated. For example, the recurring unit of formula (I) or formula (Ia) may be configured such that an R₁ comprising siloxane group is between R₂ comprising siloxane group and an R₃ comprising siloxane group. It is also contemplated that an R₃ comprising siloxane group is between an R₁ comprising siloxane group and an R₂ comprising siloxane group. Non-limiting examples of structural units of the sol-gel compositions of the present invention include, but are not limited to, the following:

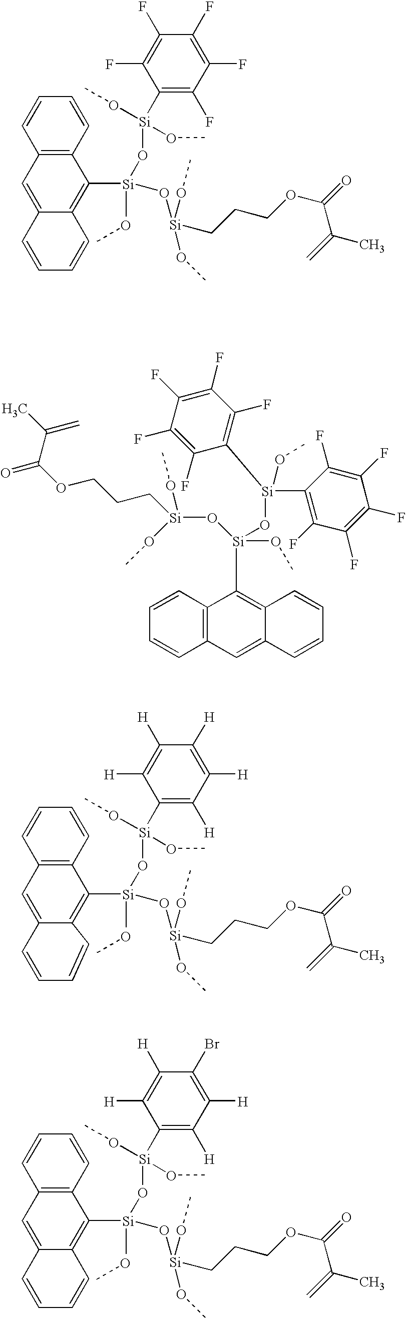

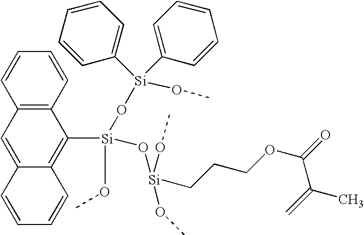

wherein each dashed line generally represents a connection to an additional siloxane unit (not shown).

The sol-gel composition can be manufactured using the processes and techniques described herein, or by adaptations of such methods. In an embodiment, a sol-gel composition is prepared according to a method that comprises an initial step of mixing two organically modified silane precursors with an aqueous acidic solution, wherein one of the silane precursors is a monomer according to the formula (V) and the other silane precursor is a monomer according to the formula (VI), as described above. Each of the monomers described herein can be used as a sol-gel precursor. As previously noted, each of the R groups in formulae (V) and (VI) is independently selected to be a lower alkyl group. A “lower alkyl group” as described herein, means a branched or unbranched C₁-C₅ alkyl group. Suitable lower alkyl groups include methyl, ethyl, n-propanyl, isopropanyl, n-butyl, isobutyl, sec-butyl, t-butyl, and pentyl (and all isomers thereof). In an embodiment, each of the R groups in formulae (V) and (VI) is independently methyl or ethyl. In an embodiment, each n in formulae (V) and (VI) is independently selected to be an integer in the range of 0 to about 5. Preferably, each n in formulae (V) and (VI) is independently selected to be an integer in the range of 0 to about 3.

It is also contemplated that the initial method step of producing the sol-gel may comprise mixing a single organically modified silane precursor with an aqueous acidic solution, rather than two organically modified silane precursors. For example, the silane precursor that is a monomer according to formula (VI) can be mixed alone with an aqueous acidic solution. Where the silane precursor comprising a structure of formula (V) is not involved in the processing steps, the sol-gel composition will typically remain substantially free of halogenated atoms. However, small amounts of the monomer according to formula (V) may be desirable to form a sol-gel composition comprising C—F bonds. A person having ordinary skill in the art, guided by the disclosure herein, can adjust the amount of C—F bonds in the sol-gel composition by adjusting the amount of silane precursor according to the monomer represent by formula (V) added to the mixture.

In an embodiment, the mixture is stirred until the —OR groups in both formulae (V) and (VI) are at least partially hydrolyzed. After the —OR groups are partially hydrolyzed, a third organically modified silane precursor can be added to the mixture, wherein the third silane precursors is a monomer according to the formula (VII). As discussed above, each R in formula (VII) is independently selected to be a lower alkyl group. Preferably, each R in formula (VII) is independently methyl or ethyl. In an embodiment, the n in formula (VII) is an integer in the range of 0 to about 5. In an embodiment, the n in formula (VII) is an integer from 0 to about 3.

The solution is then agitated (e.g., by stirring), during which the solvent can be removed in order to facilitate condensation and aging. In an embodiment, during or after the solvent is removed, additional solvent can be added while mixing in order to further complete hydrolysis. After this additional solvent is added, the solution is again aged, and the additional solvent is removed to form a viscous liquid.

In an embodiment, the initial step of mixing two organically modified sol-gel precursors is modified so that the step comprises mixing three organically modified sol-gel precursors. For example, the third modified sol-gel precursor added after the —OR groups in both formulae (V) and (VI) are at least partially hydrolyzed can instead be added in the initial step. In some embodiments, when all three organically modified sol-gel precursors are mixed and then partially hydrolyzed, no further sol-gel precursors need to be added. The solution can be agitated (e.g., by stirring), during which the solvent can be removed to facilitate condensation and aging. In an embodiment, during or after the solvent is removed, additional solvent can be added while mixing in order to further complete hydrolysis. After this additional solvent is added, the solution is again aged, and the additional solvent is removed to form a viscous liquid

In embodiments where additional solvent is added after or during the step of removing solvent, a photo-initiator can be added to the solution. Any suitable photo-initiator may be used, including those discussed above. The photo-initiator is particularly preferred when the photo cross-linkable groups for R₁ are selected from the group consisting of epoxy, vinyl, methacryloxy, and acryloxy.

Each of the monomers according to formulae (V), (VI), and (VII) comprises a sol-gel precursor. In an embodiment, each R in the monomers according to formulae (V) and (VI) is independently selected to be methyl or ethyl. In an embodiment, the monomer according to formula (V) comprises an aromatic group, such as phenyl or anthracenyl, which is substituted with fluorine and/or bromine. In an embodiment, the monomer according to formula (V) is selected from the group consisting of pentafluorophenyl trimethoxysilane, bromoanthracenyl trimethoxysilane, pentafluorophenyl triethoxysilane, bromoanthracenyl triethoxysilane, and bromophenyl trimethoxysilane. In an embodiment, the monomer according to formula (VI) comprises an unsubstituted aromatic group, such as phenyl, naphthyl, or anthracenyl. In an embodiment, the monomer according to formula (VI) is selected from the group consisting of anthracenyl trimethoxysilane, phenanthrenyl triethoxysilane, naphthyl trimethoxysilane, pyrenyl trimethoxysilane, and perylenyl triethoxysilane. In an embodiment, the monomer according to formula (VI) comprises a substituted aromatic group. For example, the aromatic group can be substituted with an additional di- or tri-aloxysilane group. One non-limiting example of such a monomer is perylenyl 3,9-bis(triethoxysilane). In an embodiment, the monomer according to formula (VI) is selected from 1-trimethoxysilylanthracene, 2-trimethoxysilylanthracene, 9-trimethoxysilylanthracene, and combinations thereof. In an embodiment, the monomer according to formula (VI) is 9-trimethoxysilylanthracene.

In an embodiment, each R in the monomer according to formula (VII) is independently selected to be methyl or ethyl. In an embodiment, the monomer according to formula (VII) is selected from the group consisting of methacryloxypropyl trimethoxysilane, methacryloxypropyl triethoxysilane, acryloxypropyl trimethoxysilane, and acryloxypropyl triethoxysilane. In an embodiment, the monomer according to formula (VII) is methacryloxypropyl trimethoxysilane.

The monomers according to formulae (V), (VI), and (VII) each describe a compound having three alkoxy groups attached to a silicon atom with a single mono-subsititution on the silicon atom of an R₁, R₂, and R₃ group, respectively. However, it is additionally contemplated that di- and tri-substituted alkoxysilane groups can also be used.

For example, in the manufacture of a sol-gel composition, a monomer according to the formula (V) as described above can be replaced with a monomer according to the formula (Va):

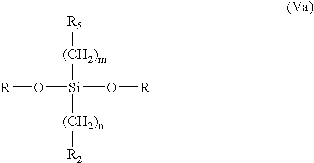

wherein R₂ and n in formula (Va) is as defined above with respect to formula (V), R₅ in formula (Va) is —OR or an aromatic group optionally substituted with at least one halogen or deuterium atom, and each R is independently selected to be a lower alkyl group. In an embodiment, m is an integer in the range of 0 to about 10. In an embodiment, m is an integer in the range of 0 to about 3. Any of the aromatic groups optionally substituted with at least one halogen or deuterium atom that are described herein can be used for R₅. Non-limiting examples of useful compounds of formula (Va) include bispentafluorophenyl dimethoxysilane and bispentafluorophenyl diethoxysilane.

Additionally, in an embodiment, a monomer according to the formula (VI) as described above in the manufacture of a sol-gel composition can be replaced with a monomer according to the formula (VIa):

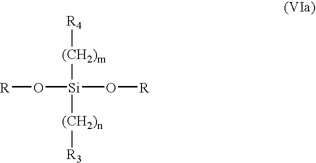

wherein R₃ and n in formula (VIa) is as defined above with respect to formula (VI), R₄ in formula (VIa) is —OR or an aromatic group selected from the group consisting of phenyl, biphenyl, naphthyl, anthracenyl, phenanthrenyl, pyrenyl, quinolinyl, tetracenyl, perylenyl, and pentacenyl, and each R is independently selected to be a lower alkyl group. In an embodiment, each m and n is independently an integer in the range of 0 to about 10. In an embodiment, each m and n is independently an integer in the range of 0 to about 3. The aromatic groups of R₃ and R₄ can be the same or different. In an embodiment, R₃ and R₄ comprise pyrenyl groups. For example, the monomer according to formula (VIa) can be selected from bis(pyrenyl) dimethoxysilane or bis(pyrenyl) diethoxysilane.

Each of the monomers according to formulae (V), (Va), (VI), (VIa), and (VII) can exist in various isomeric forms. In particular, monomers containing aromatic groups, whether substituted or unsubstituted, can have the aromatic group bonded to the silicon atom, either directly or by a linker, at any number of carbon positions on the aromatic group. Selection of a particular isomer can depend upon several factors, including ease of synthesis of the monomer. Those having ordinary skill in the art, guided by the disclosure herein, will understand that each of the isomers is contemplated as usable herein.

The sol-gels described herein can be used to form photo-patterned structures on substrates. In an embodiment, a method of making photo-patterned structures on a substrate is provided, the method comprising the initial step of coating a sol-gel on at least a portion of the substrate to form a film, wherein the sol-gel comprises a recurring unit of the formula (I) or a recurring unit of the formula (Ia), as described above. After the sol-gel film has been coated, it can be soft baked at a low temperature to remove solvent. As used herein, the term “soft bake” means a heating operation with the purpose of evaporating at least a portion of the solvents in the sol-gel film, wherein the heating conditions are at a low enough temperature and time duration such that the sol-gel film does not harden to an inflexible degree and remains soft.

The sol-gel film can then be masked. The mask is positioned over the sol-gel film and preferably has at least one opening to define a pattern design. Any suitable masking technique and masking material can be used to apply the mask. The mask protects covered areas of the sol-gel film from radiation by light. Uncovered areas, e.g. areas of the sol-gel that adjacent the openings in the mask, can be exposed to light and rendered insoluble by the radiation.

After the mask is positioned and a desired outline of a pattern created, at least a portion of the uncovered area of the sol-gel film can then be exposed to ultra-violet (U.V.) radiation through the at least one opening in the mask to render the exposed portion of the film insoluble to a selected solvent through the full thickness of the film. The sol-gel film can then be washed in the selected solvent to remove, e.g. by dissolving, the unexposed portion of the film. The dissolved portion of the sol-gel film can then be removed, thus leaving behind a desired sol-gel film pattern. The remaining sol-gel film pattern can be hardened by hard baking the film at a higher temperature in a vacuum oven. Hard baking can also further remove any solvent left over from the soft baking step. As used herein, the term “hard bake” means a heating operation at sufficient time and temperature to achieve further polymerization of the sol-gel material and adhesion of the sol-gel material to the substrate.

Various types of substrates may be used to form the photo-patterned structures thereon. In an embodiment, the substrate comprises a silicon wafer. Silicon wafers can be provided with buffer layers before the sol-gel composition is formed on the substrate. In an embodiment, the silicon wafer comprises a SiO₂ buffer layer. The buffer layer may be thermally grown on the substrate to any desired degree of thickness. For example, the buffer layer can have a thickness in the range of about 3 μm to about 20 μm. In an embodiment, the buffer layer has a thickness in the range of about 4 μm to about 10 μm. In an embodiment, the buffer layer has a thickness in the range of about 10 μm to about 15 μm. In an embodiment, the buffer layer has a thickness in the range of about 16 μm to about 20 μm.

Additional layers may be provided on top of the silicon wafer in addition to the buffer layer. In an embodiment, silicon wafer further comprises a metal layer over (e.g., on) the SiO₂ buffer layer. Useful metal layers include, but are not limited to Au, Ag, Cu, Ti, Al, Cr, Mo, and combinations and alloys thereof. The sol-gel composition can be deposited over the silicon wafer, over the buffer layer, or over the metal layer on top of the buffer layer.

The substrate can also comprise glass. The glass may also have additional buffer and/or metal layers of varying thicknesses. in an embodiment, the glass further comprises a metal layer. In an embodiment, the metal layer deposited over the glass is selected from Ti, Al, Cr, or Mo. In an embodiment, the metal layer deposited over the glass is molybdenum.

The thickness of the metal layer deposited over the glass can vary. In an embodiment, the metal layer deposited over the glass has a thickness in the range of about 50 nm to about 700 nm. In an embodiment, the metal layer deposited over the glass has a thickness in the range of about 200 nm to about 500 nm. In an embodiment, the metal layer deposited over the glass has a thickness in the range of about 50 nm to about 150 nm. In an embodiment, the metal layer deposited over the glass has a thickness in the range of about 150 nm to about 250 nm. In an embodiment, the metal layer deposited over the glass has a thickness in the range of about 250 nm to about 350 nm. In an embodiment, the metal layer deposited over the glass has a thickness in the range of about 350 nm to about 450 nm. In an embodiment, the metal layer deposited over the glass has a thickness in the range of about 450 nm to about 550 nm. In an embodiment, the metal layer deposited over the glass has a thickness in the range of about 550 nm to about 700 nm.

The following descriptions illustrate synthetic routes for the synthesis of the high refractive index component (e.g. monomers according to the formula (VI) and monomers according to the formula (VIa)). Namely, two methods of synthesis for 9-trimethoxysilylanthracene, one method of synthesis of 9-triethoxysilylanthracene, one method of synthesis of pyrenyltriethoxysilane, one method of sythesis of bispyrenyl diethoxysilane, and one method of synthesis of perylene triethoxysilane and perylene di-triethoxysilane are illustrated.

### Synthesis A: 9-trimethoxysilylanthracene

In the following, the inventors describe a synthesis procedure for 9-trimethoxysilylanthracene. Although the synthesis shown involves substitution at the 9-position of the anthracene, similar synthesis methods can be used to substitute at other positions on the anthracene ring.

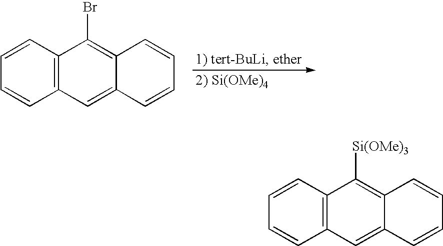

To a solution of 9-bromoanthracene (6.7 g, 20 mmol) in 150 ml anhydrous ether was slowly added t-BuLi (13 mL, 1.7 M, 22 mmol) by syringe at −78° C. under Ar while vigorously stirring. After stirring for 30 min. at −78° C., the mixture was slowly warmed up to room temperature and continued to stir for 4 hours at room temperature. Then, the mixture was cooled back to −78° C. and tetramethoxy silane (Si(OMe)₄) (5 ml, 36 mmol) was added by syringe. The resultant mixture was slowly warmed up room temperature again with continuous stirring at room temperature for 3 days under Ar.

The reaction mixture was extracted by cooled saturated ammonium chloride (aqueous)/hexane (150 ml/100 ml). The organic phase was collected, dried over anhydrous MgSO₄, and filtered. The organic solvents and excess of un-reactive Si(OMe)₄ were removed by rotary evaporator under reduced pressure at 40° C. (water bath), yielding crude product as a yellow solid. The crude product was dissolved in n-hexane and subjected to a short silica-gel column eluted by first by hexane to remove the starting material 9-bromoanthracene (it should be recovered) and followed by hexane/ethyl acetate (30:1/v:v) to get the product 9-trimethoxysilylanthracene as light yellow solid which can be further purified, if necessary, by recrystallization from hexane or distillation.

### Synthesis B: 9-trimethoxysilylanthracene

In the following, the inventors describe another synthesis procedure for 9-trimethoxysilylanthracene. Although the synthesis shown involves substitution at the 9-position of the anthracene, similar synthesis methods can be used to substitute at other positions on the anthracene ring.

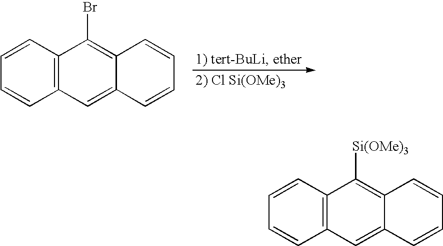

To a solution of 9-bromoanthracene (6.7 g, 20 mmol) in 150 ml anhydrous ether was slowly added t-BuLi (13 mL, 1.7 M, 22 mmol) by syringe at −78° C. under Ar while vigorously stirring. After stirring for 30 min. at −78° C., the mixture was slowly warmed up to room temperature and continued to stir for 4 hours at room temperature. Then, the mixture was cooled back to −78° C. and triethoxy silyl chloride (Cl Si(OMe)₃) (5 ml, 36 mmol) was added by syringe. The resultant mixture was slowly warmed up room temperature again with continuous stirring at room temperature for 3 days under Ar.

The reaction mixture was extracted by cooled saturated ammonium chloride (aqueous)/hexane (150 ml/100 ml). The organic phase was collected, dried over anhydrous MgSO₄, and filtered. The organic solvents and excess of un-reactive Si(OMe)₄ were removed by rotary evaporator under reduced pressure at 40° C. (water bath), yielding crude product as a yellow solid. The crude product was dissolved in n-hexane and subjected to a short silica-gel column eluted by first by hexane to remove the starting material 9-bromoanthracene (it should be recovered) and followed by hexane/ethyl acetate (30:1/v:v) to get the product 9-trimethoxysilylanthracene as light yellow solid which can be further purified, if necessary, by recrystallization from hexane or distillation.

### Synthesis C: 9-triethoxysilylanthracene

In the following, the inventors describe the synthesis procedure for 9-triethoxysilylanthracene. Although the synthesis shown involves substitution at the 9-position of the anthracene, similar synthesis methods can be used to substitute at other positions on the anthracene ring.

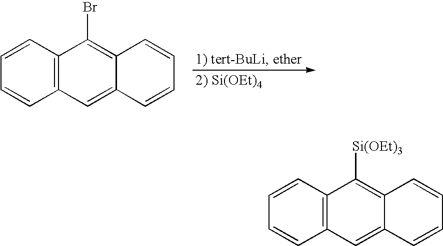

To a solution of 9-bromoanthracene (6.7 g, 20 mmol) in 150 ml anhydrous ether was slowly added t-BuLi (13 mL, 1.7 M, 22 mmol) by syringe at −78° C. under Ar while vigorously stirring. After stirring for 30 min. at −78° C., the mixture was slowly warmed up to room temperature and continued to stir for 4 hours at room temperature. Then, the mixture was cooled back to −78° C. and tetraethoxy silane (Si(OEt)₄) (5 ml, 36 mmol) was added by syringe. The resultant mixture was slowly warmed up room temperature again with continuous stirring at room temperature for 3 days under Ar.

The reaction mixture was extracted by cooled saturated ammonium chloride (aqueous)/hexane (150 ml/100 ml). The organic phase was collected, dried over anhydrous MgSO₄, and filtered. The organic solvents and excess of un-reactive Si(OEt)₄ were removed by rotary evaporator under reduced pressure at 40° C. (water bath), yielding crude product as a yellow solid. The crude product was dissolved in n-hexane and subjected to a short silica-gel column eluted by first by hexane to remove the starting material 9-bromoanthracene (it should be recovered) and followed by hexane/ethyl acetate (30:1/v:v) to get the product 9-triethoxysilylanthracene as light yellow solid which can be further purified, if necessary, by recrystallization from hexane or distillation.

### Synthesis D: pyrenyltriethoxvsilane

In the following, the inventors describe the synthesis procedure for pyrenyl triethoxysilane.

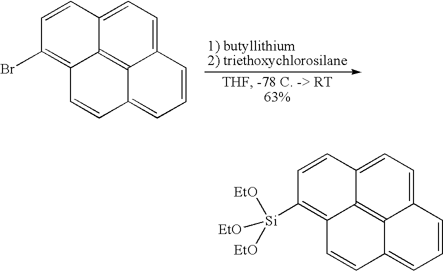

To a 50 ml single-neck round-bottom flask was added 3.29 g (11.7 mmol) of bromopyrene. This flask was stoppered with a rubber septum and evacuated via a vacuum line adapted to a syringe needle. The needle was then removed. THF was canulated into the reaction flask via a double-ended needle until the starting material dissolved (35-40 mL). A balloon charged with Ar was used to introduce an inert atmosphere. This solution was cooled to −78° C. and 8.0 mL (12.7 mmol) of n-butyllithium in hexanes was added dropwise over 5 minutes.

This yellow suspension was stirred at −78° C. for 40 minutes and then 10 g (50.3 mmol) of triethoxychlorosilane, freshly distilled from CaH₂, was added quickly via a syringe. The color dissipated and solids went into solution immediately. The reaction mixture was warmed naturally to room temperature and stirred overnight. The excess triethoxychlorosilane was quenched by treatment with 10 ml absolute anhydrous ethanol, and removed via rotory evaporation. The resultant oil was taken up in 25 mL of the elution solvent, filtered to remove LiBr, and added to a column containing a copious amount of silica gel. The column was eluted using 1:1 hexane:dichloromethane (R_{f} 0.5) and evaporated to yield a faintly yellow oil.

Pyrenyltriethoxysilane. Yield 2.7 g (63%). ¹H-NMR (400 MHz, 1,1,2,2-tetrachloroethane): d=8.61 (d; J=9.1 Hz; 1H), 8.47 (d; J=7.7 Hz; 1H), 8.24-8.04 (m; 7H), 3.90 (q; 6H), 1.26 (t; 9H).

### Synthesis E: bispyrenyl diethoxysilane

In the following, the inventors describe the synthesis procedure for bis(pyrenyl) diethoxysilane.

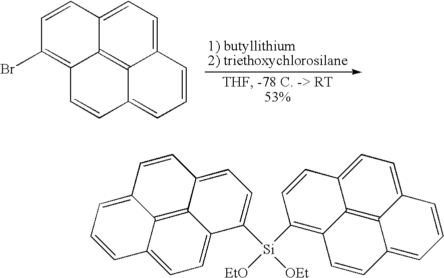

To a 50 ml single-neck round-bottom flask was added 3.73 g (13.3 mmol) of bromopyrene. This flask was stoppered with a rubber septum and evacuated via a vacuum line adapted to a syringe needle. The needle was then removed. THF was canulated into the reaction flask via a double-ended needle until the starting material dissolved (35-40 mL). A balloon charged with Ar was used to introduce an inert atmosphere. This solution was cooled to −78° C. and 9.0 mL (14.5 mmol) of n-butyllithium in hexanes was added dropwise over 5 minutes.

This yellow suspension was stirred at −78° C. for 40 minutes and then 1.32 g (6.65 mmol) of triethoxychlorosilane, freshly distilled from CaH₂, was added in quickly via a syringe. The color dissipated and solids went into solution immediately. The reaction mixture was warmed naturally to room temperature and stirred overnight. The excess triethoxychlorosilane was quenched by treatment with 10 ml absolute anhydrous ethanol, and removed via rotary evaporation. The resultant oil was taken up in 25 mL of the elution solvent, filtered to remove LiBr, and added to a column containing a copious amount of silica gel. The product was eluted with a gradient of 4:1→3:1→2:1 hexane dichloromethane. A white solid was obtained after evaporation.

Bispyrenyl diethoxysilane. Yield 1.8 g (53%). ¹H-NMR (400 MHz, 1,1,2,2-tetrachloroethane): d=8.64 (t; J=7.7 Hz; 4H), 8.23 (d; J=7.7 Hz; 2H), 8.18 (d; J=7.0 Hz; 2H), 8.14-8.10 (m; 6H), 8.00-7.95 (m; 4H), 3.96 (q; 4H), 1.32 (t; 6H). MS (Direct Insertion EI): m/z (%)=520 (100) [M]⁺, 521(39), 522 (11).

### Synthesis F: Perylene Triethoxysilane and Perdene Di-Triethoxysilane

In the following, the inventors describe the synthesis procedure for perylene triethoxysilane and perylene di-triethoxysilane.

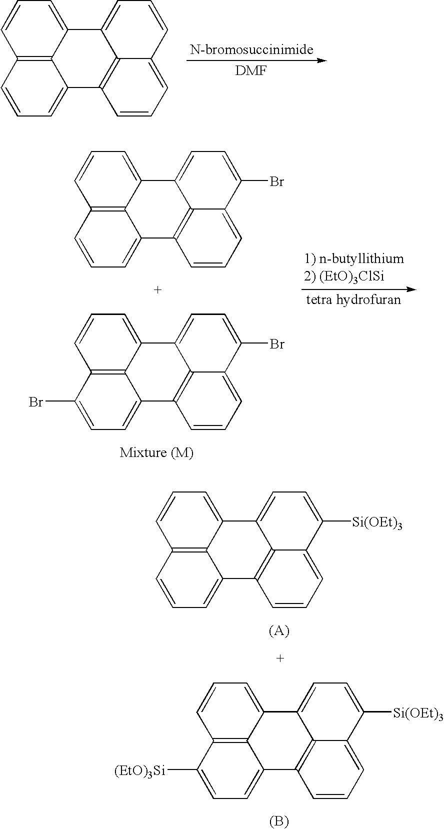

A mixture of 3-bromoperylene and 3,9-dibromoperylene (Mixture M) is first created by subjecting 20 g (80.0 mmol) of perylene to the conditions described Example 1 in European Patent Application EP 1,317,005 A2 by Oh et al., entitled “Organic electroluminescent device,” the contents of which are incorporated herein by reference in their entirty. The 20 g of perylene was dissolved in DMF, and then N-bromosuceinimide (NBS) dissolved in DMF was added dropwise until the perylene was consumed. Consummation of the perylene took place after about 12.4 g of N-bromosuccinimide was added and the solution stirred. The reaction resulted in an inseparable mixture of 3-bromoperylene and 3,9-dibromoperylene in a ratio of roughly 2:3, respectively, and a total weight of about 19.6 g.

17.0 g of Mixture M was then placed in a single-neck round bottom flask, and dissolved in 1.3 L of dry tetrahydrofuran under an inert atmosphere and cooled to −78° C. To this solution, 103 mL (165 mmol) of n-butyllithium in hexanes was added. This suspension was stirred at −78° C. for 3 hours before 50 mL (256 mmol) of triethoxychlorosilane was added. The reaction mixture was removed from the dry-ice bath, allowed to come to room temperature naturally, and then stirred overnight. The reaction mixture was poured into a separatory funnel containing 2 L of ice-cold diethyl ether. This solution was washed with an ice-cold solution of 4 g of NaOH in 2 L of water. The organic phase was washed with ice-cold water, followed by ice-cold brine. The organic phase was then dried with Na₂SO₄ and evaporated to yield a dark red oil. This oil was purified by column chromatography using a silica gel stationary phase and 1:1 toluene:dichloromethane mobile phase to yield 3-triethoxysilylperylene (A) (R_{f}=0.5) and 3,9-bis(triethoxysilyl)perylene (B) (R_{f}=0.2) as a yellow powder and red oil in equilibrium with a solid, respectively.

3-triethoxysilylperylene. Yield=3.7 g (50% estimated). ¹H-NMR (400 MHz, CD₂Cl₂): d=8.23 (m; 5H), 7.98 (m; 1H), 7.71 (t; J=8.8 Hz; 2H), 7.50 (m; 3H), 3.92 (q; 6H), 1.26 (t; 9H).

3,9-bis(triethoxysityl)perylene. Yield=4.5 g (29% estimated). ¹H-NMR (400 MHz, CD₂Cl₂): d=8.30-8.17 (m; 6H), 8.00 (dd; J₁=7.69, J₂=1.83; 2H), 7.55 (td; J1=8.42, J2=2.2), 3.90 (q; 12H), 1.24 (t; 18H).

### EXAMPLES

Various sol-gel compositions comprising a recurring unit of the formula (I) were formed by combining various monomers of the formulae (V), (VI), and/or (VII) and using the manufacturing steps described herein. The monomers of formula (V) were selected from bispentafluorophenyl dimethoxysilane (BPFPhDMS), bromophenyl trimethoxysilane (BrPhTMS), bromoanthracenyl triethoxysilane (BrAnTES), and pentafluorophenyl triethoxysilane (PFPhTES). The monomers of formula (VI) were selected from 9-trimethoxysilylanthracene (9-TMSA), naphthyl trimethoxysilane (NaphTMS), phenanthrenyl triethoxysilane (PhenTES), pyrenyl triethoxysilane (PyrTES), bis(pyrenyl) diethoxysilane (BPyrDES), perylenyl trimethoxysilane (peryTES), and 3,9-bis(triethoxysilyl)perylene (BTESPer). The monomer of formula (VII) was methacryloxypropyl trimethoxysilane (MAPTMS).

As illustrated in the Examples below, the mol percentages of siloxane units comprising a photo-crosslinkable group, siloxane units comprising an aromatic group, and siloxane units comprising an aromatic group substituted with one or more halogen or deuterium atoms in the sol-gel composition can be varied by altering the beginning portions of the monomers of the formulae (V), (VI), and (VII). Although 9-trimethoxysilylanthracene is used in the Examples, it is also contemplated that 1-trimethoxysilylanthracene, 2-trimethoxysilylanthracene, 9-trimethoxysilylanthracene, and combinations thereof can be used and offer similar properties. Therefore, any isomer of anthracenyl trimethoxysilane or combinations of isomers can be used.

### Example 1

A sol-gel composition was prepared by mixing 1.047 g of 9-trimethoxysilylanthracene and 0.871 g of methacryloxypropyl trimethoxysilane with 0.560 g of aqueous (0.01N) HCl and stirring the resulting mixture for 12 hours at ambient conditions. In this and all other examples, solvent can be removed from the mixture or additional solvent can be added, depending upon the target thickness of the films needed. The solution was aged for few hours at room temperature. Then, the photo-initiator 1-hydroxy-cyclohexyl-phenyl-ketone in an amount of 0.060 g was added to the mixture and the solution stirred for 2 hours prior to spin coating.

### Example 2

A sol-gel composition was prepared by mixing 0.628 g of 9-trimethoxysilylanthracene, 0.596 g of bispentafluorophenyl dimethoxysilane, and 0.871 g of methacryloxypropyl trimetboxysilane with 0.560 g of aqueous (0.01N) HCl and stirring for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 3

A sol-gel composition was prepared by mixing 0.628 g of 9-trimethoxysilylanthracene, 1.191 g of bispentafluorophenyl dimethoxysilane, and 0.523 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 4

A sol-gel composition was prepared by mixing 0.419 g of 9-trimethoxysitylanthracene, 1.489 g of bispentafluorophenyl dimethoxysilane, and 0.523 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 5

A sol-gel composition was prepared by mixing 0.628 g of 9-trimethoxysilylanthracene, 1.786 g of bispentafluorophenyl dimethoxysilane, and 0.174 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 6

A sol-gel composition was prepared by mixing 1 g of 9-trimethoxysilylanthracene, 0.823 g of pentafluorophenyl triethoxysilane, and 0.833 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 7

A sol-gel composition was prepared by mixing 1 g of 9-trimethoxysilylanthracene, 1.646 g of pentafluorophenyl triethoxysilane, and 1.3 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 8

A sol-gel composition was prepared by mixing 1 g of 9-trimethoxysilylanthracene, 1.290 g of pentafluorophenyl trimethoxysilane, and 0.833 g of methacryloxypropyl trimethoxysilane was mixed with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 9

A sol-gel composition was prepared by mixing 1 g of 9-trimethoxysilylanthracene, 0.615 g of bromophenyl trimethoxysilane, and 1.38 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 10

A sol-gel composition was prepared by mixing 1 g of 9-trimethoxysilylanthracene, 1.230 g of bromophenyl trimethoxysilane, and 0.833 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 11

A sol-gel composition was prepared by mixing 1 g of 9-trimethoxysilylanthracene, 0.977 g of biphenyl trimethoxysilane, and 1.380 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 12

A sol-gel composition was prepared by mixing 1 g of 9-trimethoxysilylanthracene, 1.984 g of biphenyl trimethoxysilane, and 1.380 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 13

A sol-gel composition was prepared by mixing 1 g of 9-trimethoxysilylanthracene, 0.556 g of naphthyl trimethoxysilane, and 1.380 g of methacryloxypropyl trimethoxysilane with 0.560 g ml of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 14

A sol-gel composition was prepared by mixing 1 g of 9-trimethoxysilylanthracene, 1.112 g of naphthyl trimethoxysilane, and 0.833 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 15

A sol-gel composition was prepared by mixing 1 g of phenanthrenyl triethoxysilane, 0.406 g of bromophenyl trimethoxysilane, 0.312 g of bispentafluorophenyl dimehtoxysilane, and 0.556 g of methacrytoxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 16

A sol-gel composition was prepared by mixing 1 g of phenanthrenyl triethoxysilane, 0.840 g of bispentafluorophenyl dimehtoxysilane, and 1.240 g of methaeryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 17

A sol-gel composition was prepared by mixing 1.021 g of phenanthrenyl triethoxysilane and 0.744 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 18

A sol-gel composition was prepared by mixing 1.495 g of naphthyl trimethoxysilane and 1.508 g of methacryloxypropyl trimethoxysilane with 0.750 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 19

A sol-gel composition was prepared by mixing 1.489 g of naphthyl trimethoxysilane, 0.833 g of bromophenyl triemthoxysilane, 0.654 g of bispentafluorophenyl dimethoxysilane, and 1.112 g of methacryloxypropyl trimethoxysilane with 0.791 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 20

A sol-gel composition was prepared by mixing 0.998 g of bromoanthracenyl triethoxysilane, 0.320 g of bromophenyl triemthoxysilane, 0.254 g of bispentafluorophenyl dimethoxysilane, and 0.442 g of methacryloxypropyl trimethoxysilane with 0.560 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 21

A sol-gel composition was prepared by mixing 0.503 g of bromoanthracenyl triethoxysilane, 0.085 g of bispentafluorophenyl dimethoxysilane and 0.149 g of methacryloxypropyl trimethoxysilane were mixed with 0.266 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 22

A sol-gel composition was prepared by mixing 0.419 g of bromoanthracenyl triethoxysilane, 0.169 g of bispentafluorophenyl dimethoxysilane, and 0.149 g of methacryloxypropyl trimethoxysilane with 0.222 g of aqueous (0.01N) HCl and stirring the resulting mixture for 12 hours at ambient conditions. The solution was aged for few hours at room temperature. Then, the photo-initiator 1-hydroxy-cyclohcxyl-phenyl-ketone in an amount of 0.080 g was added to the mixture and the solution stirred for 2 hours prior to spin coating.

### Example 23

A sol-gel composition was prepared by mixing 0.750 g of bromoanthracenyl triethoxysilane, 0.145 g pentafluorophenyl trimethoxysilane with 0.400 g of aqueous (0.01N) HCl and stirring the resulting mixture for 12 hours at ambient conditions. The solution was aged for few hours at room temperature prior to spin coating.

### Example 24

A sol-gel composition was prepared by mixing 0.750 g of bromoanthracenyl triethoxysilane, 0.170 g bispentafluorophenyl dimethoxysilane with 0.400 g of aqueous (0.01N) HCl and stirring the resulting mixture for 12 hours at ambient conditions. The solution was aged for few hours at room temperature prior to spin coating.

### Example 25

A sol-gel composition was prepared by mixing 0.629 g of bromoanthracenyl triethoxysilane, 0.424 g of bispentafluorophenyl dimethoxysilane, and 0.620 g of methacryloxypropyl trimethoxysilane with 0.333 g of aqueous (0.01N) HCl and stirring the resulting mixture for 12 hours at ambient conditions. The solution was aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 26

A sol-gel composition was prepared by mixing 0.370 g of pyrenyl triethoxysilane, 0.196 g of pentafluorophenyl trimethoxysilane, and 0.413 g of methacryloxypropyl trimethoxysilane with 0.198 g of aqueous (0.01N) HCl and stirring the resulting mixture for 12 hours at ambient conditions. The solution aged for a few hours at room temperature. Then, the photo-initiator 1-hydroxy-cyclohexyl-phenyl-ketone in an amount of 0.020 g was added to the mixture and the solution stirred for 2 hours prior to spin coating.

### Example 27

A sol-gel composition was prepared by mixing 0.364 g of pyrenyl triethoxysilane, 0.096 g of pentafluorophenyl trimethoxysilane, and 0.497 g of methacryloxypropyl trimethoxysilane with 0.193 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.020 g was added to the mixture and the solution stirred for 2 hours prior to spin coating.

### Example 28

A sol-gel composition was prepared by mixing 0.486 g of pyrenyl triethoxysilane, 0.096 g of pentafluorophenyl trimethoxysilane, and 0.414 g of methacryloxypropyl trimethoxysilane with 0.486 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.020 g was added to the mixture and the solution stirred for 2 hours prior to spin coating.

### Example 29

A sol-gel composition was prepared by mixing 0.364 g of pyrenyl triethoxysilane, 0.047 g of pentafluorophenyl trimethoxysilane, and 0.122 g of methacryloxypropyl trimethoxysilane, with 0.193 g of aqueous (0.01N) HCl and stirring the resulting mixture for 12 hours at ambient conditions. The solution, aged for few hours at room temperature. Then, the photo-initiator 1-hydroxy-cyclohexyl-phenyl-ketone in an amount of 0.020 g was added to the mixture and the solution stirred for 2 hours prior to spin coating.

### Example 30

A sol-gel composition was prepared by mixing 0.312 g of pyrenyl triethoxysilane (90:10) and 0.024 g of methacryloxypropyl trimethoxysilane with 0.138 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.010 g was added to the mixture and the solution stirred for 2 hours prior to spin coating.

### Example 31

A sol-gel composition was prepared by mixing 0.874 g of bispyrenyl) diethoxysilane, 0.322 g of pentafluorophenyl trimethoxysilane, and 0.690 g of methacryloxy propyl trimethoxysilane with 0.530 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.080 g was added to the mixture and the solution stirred for 2 hours prior to spin coating.

### Example 32

A sol-gel composition was prepared by mixing 0.388 g of bis(pyrenyl) diethoxysilane, 0.053 g of pentafluorophenyl trimethoxysilane, and 0.230 g of methacryloxypropyl trimethoxysilane with 0.233 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.020 g was added to the mixture and the solution stirred for 2 hours prior to spin coating.

### Example 33

A sol-gel composition was prepared by mixing 0.364 g of bispyrenyl) diethoxysilane, 0.040 g of pentafluorophenyl trimethoxysilane, and 0.138 g of methacryloxypropyl trimethoxysilane with 0.022 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.010 g was added to the mixture and the solution stirred for 2 hours prior to spin coating.

### Example 34

A sol-gel composition was prepared by mixing 1.036 g of perylenyl triethoxysilane, 0.482 g of pentafluorophenyl trimethoxysilane, and 1.035 g of methacryloxypropyl trimethoxysilane with 0.549 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.010 g was added to the mixture and the solution stirred for 2 hours prior to spin coating.

### Example 35

A sol-gel composition was prepared by mixing 1.442 g of 3,9-bis(triethoxysilyl)perylene, 0.482 g of pentafluorophenyl trimethoxysilane, and 1.035 g of methacryloxypropyl trimethoxysilane with 0.549 g of aqueous (0.01N) HCl and stirring the resulting mixture for 12 hours at ambient conditions. The solution aged for few hours at room temperature. Then, the photo-initiator 1-hydroxy-cyclohexyl-phenyl-ketone in an amount of 0.080 g was added to the mixture and the solution stirred for 2 hours prior to spin coating.

### Refractive Index

The refractive index of various sol-gel compositions provided above in the Examples were measured using a Metricon Prism coupler. The sols were spin-coated onto silicon wafers at 1000 rpm and formed into film. The sol-gel films were then cured at 150° C. for 2 hours prior to the refractive index measurements. This is a standard method used for refractive index evaluation of thin films at 1310 and 1550 nm. Results of the refractive index measurements are given in both Table 1 and Table 2.

### Optical Loss

The optical loss data obtained for the various sol-gel precursors provided above in the Examples was measured using a liquid prism technique. See C. C. Teng, Appl. Opt., 32, 1051 (1993). This method involves the translation of the sol-gel films coated on a Si wafer. The films were immersed into an index matching fluid that is commercially available. Light is coupled into the film using a prism and the light reflected at the interface of the film and the index matching liquid is monitored as function of the distance traversed by the films. The optical loss is deduced from the measurement using standard curve fitting procedure. The sol-gels were spin-coated onto silicon wafers (at least 2″ long) at 1000 rpm. The films were then cured at 150° C. for 2 hours to overnight prior to the loss measurements. Results of the optical loss measurements are given in Table 1.

The numbers and percentages indicated in both Tables 1 and 2 represent the mol percentage of the monomer precursor that forms the recurring unit in the sol-gel.

TABLE 1
Refractive Index and Optical Loss Measurement Results

| | | Refractive | |
|---|---|---|---|
| | | Index | Optical Loss |
| Example # | Sol-gel Precursor | (@1550 nm) | (dB/cm) |
| 1 | 50% 9-ATMS + 50% MAPTMS | 1.5450 | 1.34 |
| 2 | 30% 9-ATMS + 20% | 1.5245 | 0.55 |
| | BPFPhDMS + 50% | | |
| | MAPTMS | | |
| 3 | 30% 9-ATMS + 40% | 1.5174 | 0.50 |
| | BPFPhDMS + 30% | | |
| | MAPTMS | | |
| 4 | 20% 9-ATMS + 50% | 1.4975 | 0.4 |
| | BPFPhDMS + 30% | | |
| | MAPTMS | | |
| 5 | 30% 9-ATMS + 60% | 1.5118 | 0.4 |
| | BPFPhDMS + 10% | | |
| | MAPTMS | | |

9-ATMS: 9-trimethoxysilylanthracene
MAPTMS: methacryloxypropyl trimethoxysilane
BPFPhDMS: bispentafluorophenyl dimethoxysilane

TABLE 2
High Refractive Index Sol-Gel Precursors

| Example # | SG System | RI (@1310 nm) | RI (@1550 nm) |
|---|---|---|---|
| 13 | 9-ATMS (30) + NaphTMS (40) + MAPTMS (30) | 1.6122 | 1.5758 |
| 10 | 9-ATMS (30) + BrPhTMS (40) + MAPTMS (30) | 1.6034 | 1.5702 |
| 9 | 9-ATMS (30) + BrPhTMS (20) + MAPTMS(50) | 1.5910 | 1.5666 |
| 19 | NaphTMS (40) + BrPhTMS (20) + BPFPhDMS (10) + | 1.5798 | 1.5555 |
| | MAPTMS (30) | | |
| 18 | NaphTMS (50) + MAPTMS (50) | 1.5676 | 1.545 |
| 27 | NaphTMS (30) + BPFPhDMS (20) + MAPTMS(50) | 1.5283 | 1.5093 |
| 17 | PhenTES (50) + MAPTMS (50) | 1.6155 | 1.5823 |
| 15 | PhenTES (40) + BrPhTMS (20) + BPFPhDMS (10) + | 1.5984 | 1.5782 |
| | MAPTMS (30) | | |
| 16 | PhenETS (30) + BPFPhDMS (20) + MAPTMS (50) | 1.5575 | 1.5354 |
| 23 | BrAnTES (90) + BPFPhDMS (10) | 1.6944 | 1.6526 |
| 24 | BrAnTES (90) + PFPhTES (10) | 1.7008 | 1.6661 |
| 21 | BrAnTES (60) + BPFPhDMS (10) + MAPTMS (30) | 1.6190 | 1.5882 |
| 22 | BrAnTES (50) + BPFPhDMS (20) + MAPTMS (30) | 1.5972 | 1.5717 |
| 25 | BrAnTES(30) + BPFPhDMS (20) + MAPTMS (50) | 1.5525 | 1.5300 |
| 26 | PyrTES (30) + PFPhTMS (20) + MAPTMS (50) | 1.5691 | 1.5691 |
| 27 | PyrTES (30) + PFPhTMS (10) + MAPTMS (60) | 1.5985 | 1.5761 |
| 28 | PyrTES (40) + PFPhTMS (10) + MAPTMS (50) | 1.6171 | 1.5854 |
| 29 | PyrTES (60) + PFPhTMS (10) + MAPTMS (30) | 1.6659 | 1.6174 |
| 30 | PyrTES (90) + MAPTMS (10) | 1.7523 | 1.7310 |
| 31 | BpyrDES (30) + PFPhTMS (20) + MAPTMS (50) | 1.6609 | 1.6230 |
| 32 | BpyrDES (40) + PFPhTMS (10) + MAPTMS (50) | 1.6784 | 16372 |
| 33 | BpyrDES (60) + PFPhTMS (10) + MAPTMS (30) | 1.7193 | 1.6675 |
| 34 | PeryTES (30) + PFPhTMS (20) + MAPTMS (50) | 1.6376 | 1.5902 |
| 35 | BTESPer (30) + PFPhTMS (20) + MAPTMS (50) | 1.6196 | 1.5585 |

NaphTMS: naphthyl trimethoxysilane
BrPhTMS: bromophenyl trimethoxysilane
PhenTES: phenanthrenyl triethoxysilane
BrAnTES: bromoanthracenyl triethoxysilane
PyrTES: pyrenyl triethoxysilane
BpyrDES: bis(pyrenyl) diethoxysilane
PeryTES: perylenyl trimethoxysilane
BTESPer: 3,9-bis(triethoxysilyl)perylene
PFPhTMS: pentafluorophenyl trimethoxysilane
9-ATMS: 9-trimethoxysilylanthracene
MAPTMS: methacryloxypropyl trimethoxysilane
BPFPhDMS: bispentafluorophenyl dimethoxysilane

### Electrical Conductivity

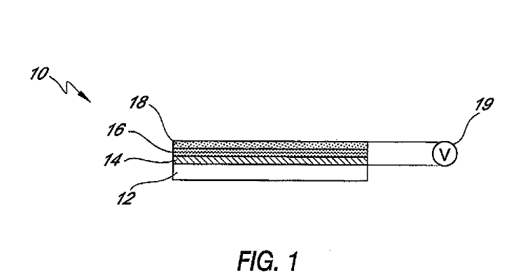

FIG. 1 illustrates an embodiment of a wafer comprising a sol-gel composition and how the electrical conductivity can be measured. The structure 10 comprises a substrate 12, such as glass, having a metal layer 14, such as molybdenum deposited thereon. The sol-gel composition 16 is spin coated on top of the metal layer 14, and the sol-gel films can be cured at 150° C. for 2 hours prior to the conductivity measurements. Then a second metal layer 18, such as gold, is formed by sputtering over the sol-gel composition. Electrical leads from a voltage meter 19 can be connected to the sample via the metal layer 14 (bottom electrode) and metal layer 18 (top electrode).

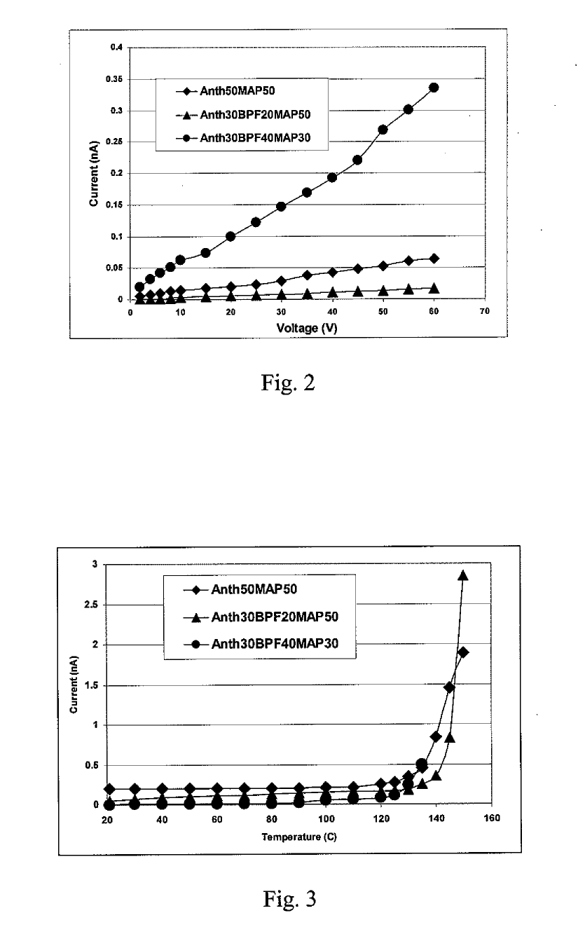

Current measurements described below were performed on three samples (Examples 1-3 described above) using the experimental set-up shown in FIG. 1 by applying a bias voltage at both room temperature and also as a function of temperature up to 150° C. In FIGS. 2 and 3, the measurements on Example 1 are represented by Anth50MAP50, the measurements of Example 2 are represented by Anth30BPF20MAP50, and the measurements of Example 3 are represented by Anth30BPF40MAP30. FIG. 2 shows a graph of the electrical current measured as a function of bias voltage at room temperature (about 21° C.). FIG. 3 shows a graph the electrical current measured as a function of temperature (between about 21 and about 150° C.).

1. A sol-gel composition comprising a recurring unit of the formula (I): 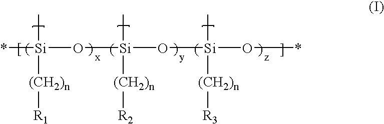
wherein R₁ is a photo cross-linkable group, R₂ is an aromatic group substituted with at least one halogen or deuterium atom, R₃ is an aromatic group selected from the group consisting of phenyl, biphenyl, naphthyl, anthracenyl, phenanthrenyl, pyrenyl, quinolinyl, tetracenyl, perylenyl, and pentacenyl, each n is independently an integer in the range of 0 to about 10, x is 1, y is 0 or 1, and z is 0 or 1, provided that at least one of y or z is 1.

2. The sol-gel composition according to claim 1, wherein the composition comprises a mole percentage of recurring units of the formula (II): 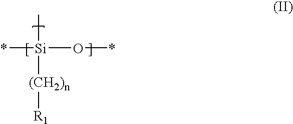
wherein R₁ is a photo cross-linkable group, n is an integer in the range of 0 to about 10, and the mole percentage of recurring units of the formula (II) is in the range of about 10 mol % to about 90 mol %.

3. The sol-gel composition according to claim 2, wherein the mole percentage of recurring units of the formula (II) is in the range of about 30 mol % to about 70 mol %.

4. The sol-gel composition according to claim 1, wherein the composition comprises a mole percentage of recurring units of the formula (III): 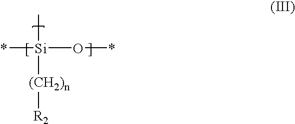
wherein R₂ is an aromatic group substituted with halogen or deuterium atoms, n is an integer in the range of 0 to about 10, and the mole percentage of recurring units of the formula (III) is in the range of about 0 mol % to about 60 mol %.

5. The sol-gel composition according to claim 4, wherein the mole percentage of recurring units of the formula (III) is in the range of about 10 mol % to about 30 mol %.

6. The sol-gel composition according to claim 1, wherein the composition comprises a mole percentage of recurring units of the formula (IV): 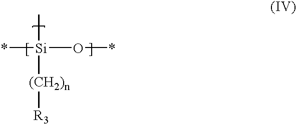
wherein R₃ is an aromatic group selected from the group consisting of phenyl, biphenyl, naphthyl, anthracenyl, phenanthrenyl, pyrenyl, quinolinyl, tetracenyl, perylenyl, and pentacenyl, n is an integer in the range of 0 to about 10, and the mole percentage of recurring units of the formula (IV) is in the range of about 10 mol % to about 90 mol %.

7. The sol-gel composition according to claim 6, wherein the mole percentage of recurring units of the formula (IV) is in the range of about 20 mol % to about 60 mol %.

8. The sol-gel composition according to claim 1, wherein the photo cross-linkable group is selected from the group consisting of methacrylate and vinyl.

9. The sol-gel composition according to claim 1, wherein the photo cross-linkable group is selected from the group consisting of epoxy, vinyl, methacryloxy, and acryloxy, and wherein the composition further comprises an amount of a photo-initiator.

10. The sol-gel composition according to claim 1, wherein the aromatic group substituted with at least one halogen atom comprises a bromoanthracenyl group.

11. The sol-gel composition according to claim 1, wherein the sol-gel composition has a refractive index greater than about 1.45 and an optical loss less than about 1.5 dB/cm measured at a telecommunication wavelength in the range of about 1300 to about 1600 nm.

12. The sol-gel composition according to claim 1, wherein the sol-gel composition has a refractive index greater than about 1.50 and an optical loss less than about 1.0 dB/cm measured at a telecommunication wavelength in the range of about 1300 to about 1600 nm.

13. A sol-gel composition prepared according to a method that comprises the steps of:
(a) mixing two organically modified silane precursors with an aqueous acidic solution to form a mixture, wherein one of the silane precursors is a monomer according to the formula (V) and the other silane precursor is a monomer according to the formula (VI): 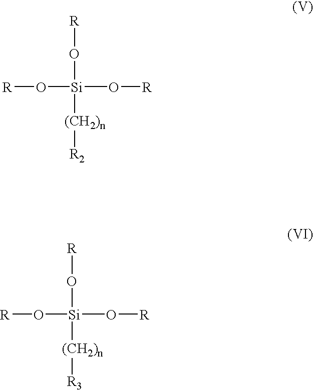
wherein R₂ in formula (V) is an aromatic group substituted with at least one halogen or deuterium atom, R₃ in formula (VI) is an aromatic group selected from the group consisting of phenyl, biphenyl, naphthyl, anthracenyl, phenanthrenyl, pyrenyl, quinolinyl, tetracenyl, perylenyl, and pentacenyl, each R in formulae (V) and (VI) is independently selected to be a lower alkyl group, and each n in formulae (V) and (VI) is independently an integer in the range of from 0 to about 10;
(b) agitating the mixture until the —OR groups in formulae (V) and (VI) are at least partially hydrolyzed;
(c) adding a third organically modified silane precursor to the resulting mixture, wherein the third organically modified silane precursor is a monomer according to the formula (VII): 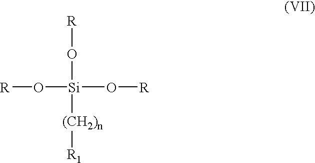
wherein R₁ in formula (VII) is a photo cross-linkable group, each R in formula (VII) is independently selected to be a lower alkyl group, and n in formula (VII) is an integer from 0 to about 10;
(d) agitating the resulting mixture;
(e) adding additional solvent to the mixture formed in step (d); and
(f) aging the product of step (e) to form a viscous liquid.

14. The sol-gel composition according to claim 13, wherein step (c) is combined into step (a) before agitating step (b), such that all three organically modified silane precursors according to formulae (V), (VI), and (VII) are mixed in the initial step (a) and partially hydrolyzed in agitating step (b).

15. The sol-gel composition according to claim 13, wherein the photo cross-linkable group is selected from the group consisting of epoxy, vinyl, methacryloxy, and acryloxy and a small amount of photo-initiator is added to the solution during step (e).

16. A method of forming a sol-gel composition that comprises:
(a) mixing two organically modified silane precursors with an aqueous acidic solution to form a mixture, wherein one of the silane precursors is a monomer according to the formula (V) and the other silane precursor is a monomer according to the formula (VI): 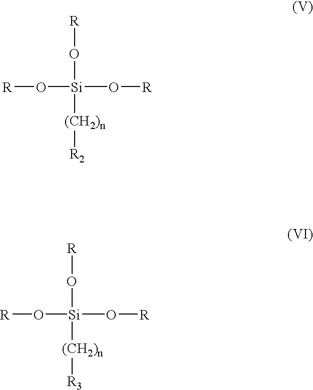
wherein R₂ in formula (V) is an aromatic group substituted with at least one halogen or deuterium atom, R₃ in formula (VI) is an aromatic group selected from the group consisting of phenyl, biphenyl, naphthyl, anthracenyl, phenanthrenyl, pyrenyl, quinolinyl, tetracenyl, perylenyl and pentacenyl, each R in formulae (V) and (VI) is independently selected to be a lower alkyl group, and each n in formulae (V) and (VI) is independently an integer from 0 to about 10;
(b) agitating the mixture until the —OR groups in formulae (V) and (VI) are at least partially hydrolyzed;
(c) adding a third organically modified silane precursor to the resulting mixture, wherein the third organically modified silane precursor is a monomer according to the formula (VII): 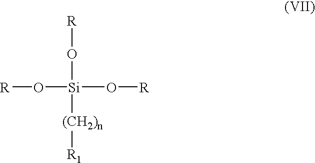
wherein R₁ in formula (VII) is a photo cross-linkable group, each R in formula (VII) is independently selected to be a lower alkyl group, and n in formula (VII) is an integer in the range of from 0 to about 10;
(d) agitating the resulting mixture;
(e) adding additional solvent to the mixture formed in step (d); and
(f) aging the product of step (e) to form a viscous liquid.

17. The method according to claim 16, wherein step (c) is combined into step (a) before agitating step (b), such that all three organically modified silane precursors according to formulae (V), (VI), and (VII) are mixed in the initial step (a) and partially hydrolyzed in agitating step (b).

18. The method composition according to claim 16, wherein the photo cross-linkable group is selected from the group consisting of epoxy, vinyl, methacryloxy, and acryloxy and a small amount of photo-initiator is added to the solution during step (e).

19. A method of making photo-patterned structures on a substrate comprising:
(a) coating a sol-gel on at least a portion of the substrate to form a film, wherein the sol-gel comprises a recurring unit of the formula (I): 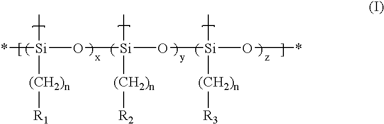
wherein R₁ is a photo cross-linkable group, R₂ is an aromatic group substituted with at least one halogen or deuterium atom, R₃ is an aromatic group selected from the group consisting of phenyl, biphenyl, naphthyl, anthracenyl, phenanthrenyl, pyrenyl, quinolinyl, tetracenyl, peryleneyl, and pentacenyl, each n is independently an integer from 0 to about 10, x is 1, y is 0 or 1, and z is 1;
(b) soft baking the film to form a sol-gel film;
(c) positioning a mask over the sol-gel film, wherein the mask comprises at least one opening that defines a pattern design;
(d) exposing at least a portion of the sol-gel film to ultra-violet radiation through the at least one opening in the mask to render an exposed portion of the film insoluble to a selected solvent through the full thickness of the film;
(e) removing an unexposed portion of the film by washing it with the selected solvent; and
(f) hard baking the film at a reduced pressure.

20. The method according to claim 19, wherein the substrate is a silicon wafer comprising a SiO₂ buffer layer.

21. The method according to claim 20, wherein the SiO₂ buffer layer has a thickness in the range of about 3 μm to about 20 μm.

22. The method according to claim 20, wherein the silicon wafer further comprises a metal layer over the SiO₂ buffer layer, wherein the metal layer is selected from Ti, Al, Cr, or Mo.

23. The method according to claim 19, wherein the substrate comprises glass that further comprises a molybdenum metal layer.

24. The method according to claim 23, wherein the molybdenum metal layer has a thickness in the range of about 50 nm to about 700 nm.

25. A sol-gel precursor comprising a compound according to the formula (VIa): 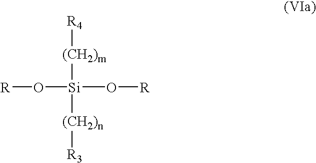
wherein R₃ is an aromatic group selected from the group consisting of phenyl, biphenyl, naphthyl, anthracenyl, phenanthrenyl, pyrenyl, quinolinyl, tetracenyl, perylenyl, and pentacenyl;
R₄ is —OR or an aromatic group selected from the group consisting of phenyl, biphenyl, naphthyl, anthracenyl, phenanthrenyl, pyrenyl, quinolinyl, tetracenyl, perylenyl, and pentacenyl;
each R is independently selected to be a lower alkyl group;
m and n are each independently selected to be an integer in the range of 0 to about 10.

26. The sol-gel precursor according to claim 25, wherein the compound is selected from the group consisting of anthracenyl trimethoxysilane, phenanthrenyl triethoxysilane, naphthyl trimethoxysilane, pyrenyl trimethoxysilane, bis(pyrenyl) dimethoxysilane, bis(pyrenyl) diethoxysilane, perylenyl triethoxysilane, and perylenyl 3,9-bis(triethoxysilane).

27. A sol-gel composition comprising a recurring unit of the formula (Ia): 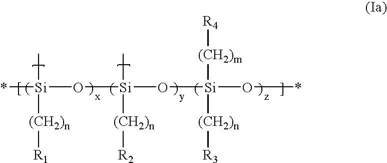
wherein R₁ is a photo cross-linkable group, R₂ is an aromatic group substituted with at least one halogen or deuterium atom, R₃ is an aromatic group selected from the group consisting of phenyl, biphenyl, naphthyl, anthracenyl, phenanthrenyl, pyrenyl, quinolinyl, tetracenyl, perylenyl, and pentacenyl;
R₄ is —OR or an aromatic group selected from the group consisting of phenyl, biphenyl, naphthyl, anthracenyl, phenanthrenyl, pyrenyl, quinolinyl, tetracenyl, perylenyl, and pentacenyl;
R is a lower alkyl group;
m and each n is independently an integer in the range of 0 to about 10, x is 1, y is 0 or 1, and z is 0 or 1, provided that at least one of y or z is 1.

28. The sol-gel composition according to claim 14, wherein the photo cross-linkable group is selected from the group consisting of epoxy, vinyl, methacryloxy, and acryloxy and a small amount of photo-initiator is added to the solution during step (e).

29. The method composition according to claim 17, wherein the photo cross-linkable group is selected from the group consisting of epoxy, vinyl, methacryloxy, and acryloxy and a small amount of photo-initiator is added to the solution during step (e).

30. The method according to claim 21, wherein the silicon wafer further comprises a metal layer over the SiO₂ buffer layer, wherein the metal layer is selected from Ti, Al, Cr, or Mo.
